(19) United States
(12) Patent Application Publication
(10) Pub. No.: US 2026/0223299 A1
(43) Pub. Date: Jul. 30, 2026

(54) DISPLAY APPARATUS

(71) Applicants: Beijing BOE Display Technology Co., Ltd., Beijing (CN); BOE Technology Group Co., Ltd., Beijing (CN)

(72) Inventors: Yang SHI, Beijing (CN); Zhengyan WAN, Beijing (CN); Jianting WANG, Beijing (CN); Rui GUO, Beijing (CN); Tianyang HAN, Beijing (CN)

(21) Appl. No.: 19/159,124

(22) PCT Filed: Jun. 12, 2024
(86) PCT No.: PCT/CN2024/098551

§ 371 Date: Aug. 22, 2025

(30) Foreign Application Priority Data
Jul. 27, 2023 (CN) 202310932292.1

(51) Int. Cl. H05K 5/02; H05K 7/20

(52) U.S. Cl. CPC H05K 5/0217; H05K 7/20963

(57) ABSTRACT

A display apparatus, including: a display module including first and second faces opposite to each other, and a side face connected therebetween, where at least part of the first face is a display surface; and a plurality of side frames at a periphery of the display module, where at least one of the side frames includes a first sidewall, and a support post and a plurality of heat dissipation protrusions arranged at intervals on the first sidewall, the first sidewall is opposite to the side face of the display module, the support post and the plurality of heat dissipation protrusions are on a side of the first sidewall facing the display module, and the support post contacts the side face of the display module and has a height greater than the heat dissipation protrusions, such that a gap is formed between the display module and the heat dissipation protrusions.

### TECHNICAL FIELD

The present disclosure relates to the field of display technology, and specifically relates to a display apparatus.

### BACKGROUND

The high-brightness liquid crystal screen is a product with a higher luminance than conventional liquid crystal screens. The high-brightness liquid crystal screen may have a luminance up to 2000 nits, while the conventional liquid crystal screen typically has a luminance of about 500 nits, which makes it hard to be seen clearly outdoors. The high-brightness liquid crystal screen is based on the principle that a backlight thereof has a higher emission luminance which can exceed the outdoor maximum luminance, i.e., 2000 nits, so that the screen is clear and visible even under outdoor strong light. The high-brightness liquid crystal screen is widely applied to bus stop boards, outdoor advertising machines, charging piles, gas stations, delivery lockers, self-service inquiry machines of telecommunication offices, tax administrations, banks, hospitals and the like, and electronic bulletin boards at city streets, parks, schools and the like. In addition, the high-brightness liquid crystal screen is also widely applied to the fields of industry, security and protection, business display, media, real estate and the like.

### SUMMARY

The present disclosure proposes a display apparatus.

The present disclosure provides a display apparatus, including:
a display module including a first face and a second face opposite to each other, and a side face connected between the first face and the second face, wherein at least part of the first face is a display surface; and
a plurality of side frames at a periphery of the display module, wherein at least one of the side frames includes a first sidewall, and a support post and a plurality of heat dissipation protrusions arranged at intervals on the first sidewall, the first sidewall is opposite to the side face of the display module, the support post and the plurality of heat dissipation protrusions are on a side of the first sidewall facing the display module, and the support post contacts the side face of the display module and has a height greater than the heat dissipation protrusions, such that a gap is formed between the display module and the heat dissipation protrusions.

In some embodiments, a height difference between the support post and the heat dissipation protrusions is in a range of 0.5 mm to 1 mm.

In some embodiments, the first sidewall has a thickness in a range of 1.5 mm to 3 mm.

In some embodiments, at least one of the side frames further includes a second sidewall connected to the first sidewall, wherein at least part of the second sidewall is on a side of the display module away from the second face; and
a recess is provided on a side of the second sidewall facing the first face.

In some embodiments, the recess has a depth in a range of 0.5 mm to 1.0 mm.

In some embodiments, the second sidewall includes a first edge away from the first sidewall and extending along a length direction of the side frame, and a distance between the first edge and the recess is in a range of 0.5 mm to 1.0 mm.

In some embodiments, a distance between a recess bottom face of the recess facing the first face and a surface of the second sidewall facing away from the first face is in a range of 1.0 mm to 3.0 mm.

In some embodiments, the plurality of heat dissipation protrusions include: at least one of a plurality of first heat dissipation fins, a plurality of second heat dissipation fins, or a plurality of heat dissipation columns;
wherein the plurality of first heat dissipation fins are arranged in a thickness direction of the display module, and each first heat dissipation fin extends along a length direction of the first sidewall;
the plurality of second heat dissipation fins are arranged in the length direction of the first sidewall, and each second heat dissipation fin extends along the thickness direction of the display module; and
the plurality of heat dissipation columns are arranged in an array.

In some embodiments, the heat dissipation protrusions include the plurality of first heat dissipation fins, each of which has a thickness in a range of 1.5 mm to 3 mm, and a distance between two adjacent first heat dissipation fins is in a range of 1.5 mm to 2.5 mm.

In some embodiments, the plurality of heat dissipation protrusions include the plurality of second heat dissipation fins, each of which has a thickness in a range of 1.5 mm to 3 mm, and a distance between two adjacent second heat dissipation fins is in a range of 1.5 mm to 2.5 mm.

In some embodiments, the plurality of heat dissipation protrusions include the plurality of heat dissipation columns, each of which has a size in the thickness direction of the display module and a size in the length direction of the first sidewall both in a range of 1.5 mm to 3 mm, and a distance between two adjacent heat dissipation columns in a same row and a distance between two adjacent heat dissipation columns in a same column are both in a range of 1.5 mm to 2.5 mm.

In some embodiments, the plurality of side frames include at least one first side frame and at least one second side frame on two adjacent sides of the display module and detachably connected; and
each of the first side frame and the second side frame includes the first sidewall, the support post, and the heat dissipation protrusions.

In some embodiments, each of the first side frame and the second side frame includes a second sidewall connected to the first sidewall and at least partially on a side of the display module away from the second face;
a first mating part is provided at an end of the second sidewall of the first side frame close to the second side frame, and the second sidewall of the second side frame includes a second mating part matched with the first mating part to form a first limit structure; and
the first side frame further includes a third mating part opposite to the second sidewall of the first side frame and connected to the first sidewall of the first side frame; the second side frame further includes a fourth mating part opposite to the second sidewall of the second side frame and connected to the first sidewall of the second side frame; and the third mating part is matched with the fourth mating part to form a second limit structure.

In some embodiments, the first mating part includes a mortise structure on the first side frame and including a first bottom face facing the third mating part and a first side face connected to the first bottom face; and the second mating part includes a second side face attached to the first side face, wherein the first side face and the second side face are both inclined.

In some embodiments, a first mounting hole is provided in the third mating part, and a second mounting hole opposite to the first mounting hole is provided in the fourth mating part; and the display apparatus further includes a first fastener running through the first mounting hole and the second mounting hole and configured to detachably connect the first side frame and the second side frame.

In some embodiments, the display apparatus further includes a rear case including a case bottom wall and a case sidewall connected to the case bottom wall, the case bottom wall and the case sidewall define a receiving space, and the case bottom wall is on a side of the receiving space away from the display module; and
the side frame further includes a mounting wall fixedly connected to the first sidewall and located in the receiving space, and the mounting wall is connected to the case sidewall.

In some embodiments, the mounting wall is provided with a third mounting hole, and the case sidewall is provided with a fourth mounting hole; the display apparatus further includes a second fastener running through the fourth mounting hole and extending into the third mounting hole, and configured to detachably connect the mounting wall and the case sidewall; and
the case sidewall includes a concave part in which the fourth mounting hole is provided.

In some embodiments, the support post is connected to the first sidewall to form an integral structure.

In some embodiments, the support post is a conductor, including a support body and an embedded part connected to the support body, the support body is on a side of the embedded part facing the display module, and an orthographic projection of the embedded part on the side face of the display module covers and exceeds an orthographic projection of the support body on the side face of the display module; and the embedded part is embedded into the first sidewall.

In some embodiments, the embedded part is embedded into the first sidewall by a depth in a range of 1.5 mm to 2.5 mm.

In some embodiments, the first sidewall is provided with an embedded groove, the embedded part is embedded into the first sidewall from a sidewall of the embedded groove, and the embedded part is embedded into the first sidewall by a width in a range of 1.0 mm to 2.0 mm.

In some embodiments, the support post is provided with a fifth mounting hole, and the display apparatus further includes a fifth fastener running through the fifth mounting hole and connected to the display module.

### BRIEF DESCRIPTION OF DRAWINGS

Accompanying drawings are provided for further understanding of the present disclosure and constitute a part of the specification. Hereinafter, these drawings are intended to explain the present disclosure together with the following specific implementations, but should not be considered as a limitation of the present disclosure. In the drawings:

FIG. 1 is a schematic overview of a display apparatus according to some embodiments of the present disclosure.

FIG. 2 is a schematic diagram showing connection of a plurality of side frames of a display apparatus according to some embodiments of the present disclosure.

FIG. 3 is an exploded view of a plurality of side frames according to some embodiments of the present disclosure.

FIG. 4 is a sectional view taken along line A-A′ in FIG. 1.

FIG. 5 is a partial schematic diagram of a display module according to some embodiments of the present disclosure.

FIG. 6 is a sectional view of one side frame according to some embodiments of the present disclosure.

FIGS. 7 to 12 are six distribution patterns of heat dissipation protrusions according to some embodiments of the present disclosure.

FIG. 13 is a schematic diagram of a rear case according to some embodiments of the present disclosure.

FIG. 14A is a plan view of a first side frame according to some embodiments of the present disclosure.

FIG. 14B is an enlarged partial view of region Q1 in FIG. 14A.

FIG. 15 is a perspective view of region Q1 in FIG. 14A.

FIG. 16 is a perspective view of a second side frame according to some embodiments of the present disclosure.

FIG. 17 is a partial perspective view of a second side frame according to some embodiments of the present disclosure.

FIG. 18 is a sectional view showing a connection position between a first side frame and a second side frame according to some embodiments of the present disclosure.

FIG. 19 is a schematic diagram of a support post and a first sidewall according to some embodiments of the present disclosure.

FIG. 20 is another schematic diagram of a support post and a first sidewall according to some embodiments of the present disclosure.

FIG. 21 is a perspective view of a second side frame at a position close to a third side frame according to some embodiments of the present disclosure.

FIG. 22 is a schematic diagram of a third side frame according to some embodiments of the present disclosure.

### DETAIL DESCRIPTION OF EMBODIMENTS

Hereinafter, specific implementations of the present disclosure will be described with respect to the accompanying drawings. It will be appreciated that the specific implementations as set forth herein are merely for the purpose of illustration and explanation of the present disclosure and should not be constructed as a limitation thereof.

To make the objects, technical solutions and advantages of the embodiments of the present disclosure more apparent, the technical solutions according to the embodiments of the present disclosure will be clearly and completely described below with reference to the drawings of the embodiments of the present disclosure. Apparently, the described embodiments are some, but not all, of the embodiments of the present disclosure. All other embodiments obtained by those of ordinary skill in the art based on the embodiments of the present disclosure described herein without paying any creative effort shall be included in the protection scope of the present disclosure.

Unless otherwise defined, technical or scientific terms used in the embodiments of the present disclosure are intended to have general meanings as understood by those of ordinary skill in the art to which the present disclosure belongs. The words “first”, “second” and similar terms used in the present disclosure do not denote any order, quantity, or importance, but are used merely for distinguishing different components from each other. Likewise, the word “comprising” or “including” or the like means that the element or item preceding the word contains elements or items that appear after the word or equivalents thereof, but does not exclude other elements or items. The terms “connected” or “coupled” and the like are not restricted to physical or mechanical connection, but may include electrical connection, either direct or indirect. The words “upper”, “lower”, “left”, “right”, or the like are merely used to indicate a relative positional relationship, and when an absolute position of the described object is changed, the relative positional relationship may be changed accordingly.

As used herein, “parallel” or “perpendicular” includes the recited case and cases that approximate the recited case to within an acceptable range of deviation as determined by one of ordinary skill in the art in view of the measurement in question and the error associated with the measurement of the particular quantity (i.e., the limitations of the measurement system). For example, “parallel” includes “absolutely parallel” and “approximately parallel”, where an acceptable deviation of “approximately parallel” may be, for example, within 5°; and “perpendicular” includes “absolutely perpendicular” and “approximately perpendicular”, where an acceptable deviation of “approximately perpendicular” may also be, for example, within 5°.

It will be understood that when a layer or element is referred to as being “on” another layer or substrate, it may be directly on the other layer or substrate, or intervening layers may be present.

Exemplary implementations are described herein with reference to cross-sectional and/or plan views as idealized exemplary figures. In the drawings, the thicknesses of layers and regions are exaggerated for clarity. Variations from the shapes in the figures as a result of, for example, manufacturing techniques and/or tolerances, are to be expected. Therefore, exemplary implementations should not be construed as limited to the shapes of regions illustrated herein, but are to include deviations in shapes that result, for example, from manufacturing. For example, an etched region shown as a rectangle will typically have curved features. Therefore, the regions illustrated in the figures are schematic in nature, and their shapes are not intended to illustrate the actual shape of a region of a device, or intended to limit the scope of exemplary implementations.

It should be noted that, in the embodiments of the present disclosure, the description of the numerical range “m1 to m2” includes the end points m1 and m2.

The high-brightness liquid crystal screen is a product with a higher luminance than conventional liquid crystal screens. The high-brightness liquid crystal screen may have a luminance up to 2000 nits, while the conventional liquid crystal screen typically has a luminance of about 500 nits, which makes it hard to be seen clearly outdoors. The high-brightness liquid crystal screen is based on the principle that a backlight thereof has a higher emission luminance which can exceed the outdoor maximum luminance, i.e., 2000 nits, so that the screen is clear and visible even under outdoor strong light. The high-brightness liquid crystal screen is widely applied to bus stop boards, outdoor advertising machines, charging piles, gas stations, delivery lockers, self-service inquiry machines of telecommunication offices, tax administrations, banks, hospitals and the like, and electronic bulletin boards at city streets, parks, schools and the like. In addition, the high-brightness liquid crystal screen is also widely applied to the fields of industry, security and protection, business display, media, real estate and the like.

However, high-brightness display means high power consumption, which leads to an extremely high heat source efficiency of the product. Normal use of the product can be guaranteed through effective heat dissipation means, but how to reduce the temperature of the product surface part while ensuring a normal use temperature of the product, so as to avoid notable discomfort of a user due to the increased product surface temperature, is an urgent technical problem to be solved in the art.

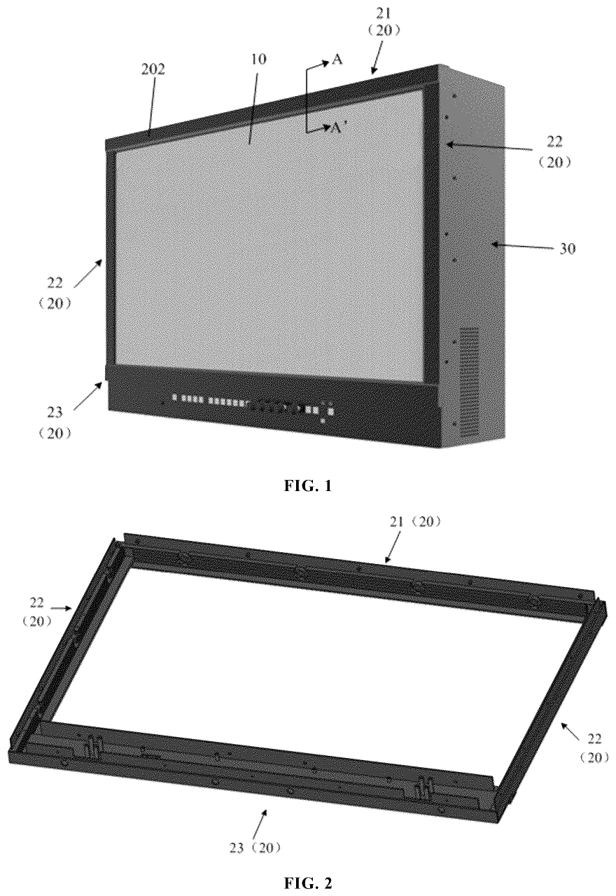

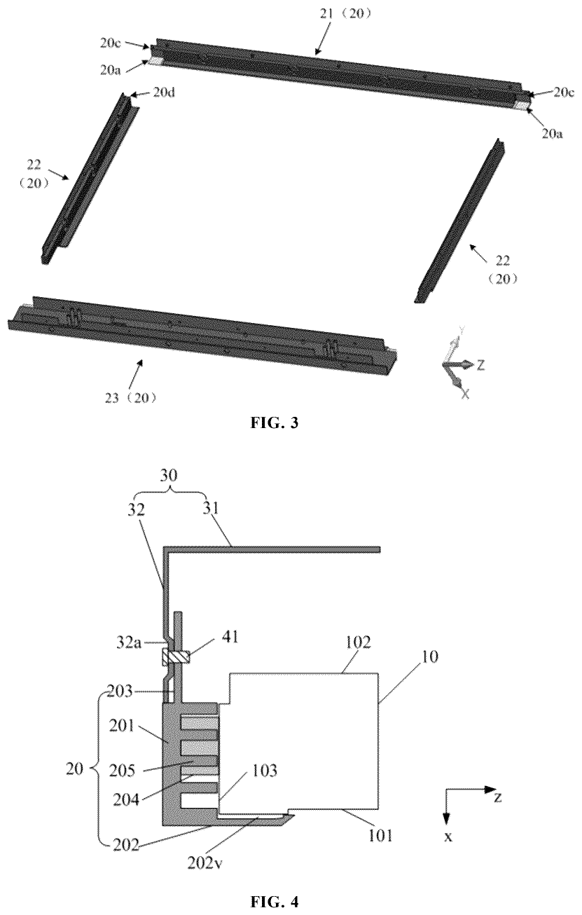

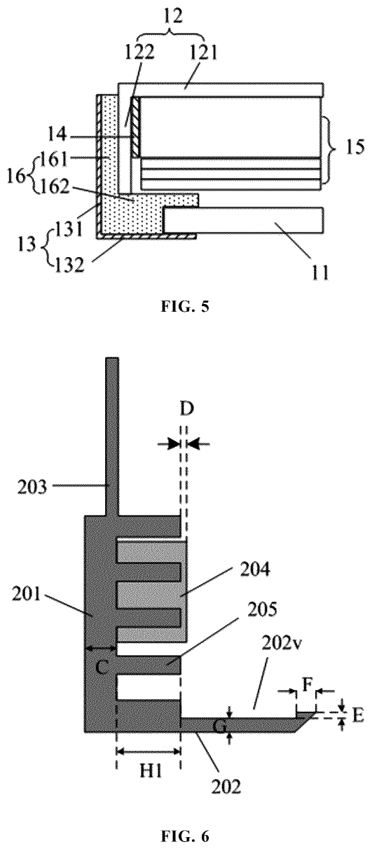

FIG. 1 is a schematic overview of a display apparatus according to some embodiments of the present disclosure, FIG. 2 is a schematic diagram showing connection of a plurality of side frames of a display apparatus according to some embodiments of the present disclosure, FIG. 3 is an exploded view of a plurality of side frames according to some embodiments of the present disclosure, FIG. 4 is a sectional view taken along line A-A′ in FIG. 1, FIG. 5 is a partial schematic diagram of a display module according to some embodiments of the present disclosure, and FIG. 6 is a sectional view of one side frame according to some embodiments of the present disclosure. As shown in FIGS. 1 to 6, the display apparatus includes a display module 10, and a plurality of side frames 20 at a periphery of the display module 10. For example, the display module 10 has a rectangular structure, each side of which is provided with a side frame 20.

The display module 10 may be a liquid crystal display module 10, which may include a liquid crystal display panel 11 and a backlight. In some examples, the display module 10 may be, in particular, a high-brightness display module 10, which may further include a drive structure such as a drive circuit board located on a side of the backlight away from the liquid crystal display panel 11.

The display module 10 includes a first face 101 and a second face 102 opposite to each other, and a side face 103 connected therebetween, where at least part of the first face 101 is a display surface. In other words, a surface of the display module 10 facing a user is the first face 101. The first face 101 may be a flat surface or an uneven surface. For example, the display module 10 includes a liquid crystal display panel 11 and a backlight, and may further include a front frame 13. A surface of the display panel 11 away from the backlight includes a display region and a non-display region. The front frame 13 includes a shielding part 132 covering the non-display region. In this case, the first face 101 includes: a portion in the display region (i.e., the display surface) of the surface of the display panel 11 away from the backlight, and a surface of the shielding part 132 away from the display panel 11.

At least one of the side frames 20 includes a first sidewall 201, and a support post 204 and a plurality of heat dissipation protrusions 205 arranged at intervals on the first sidewall 201. The first sidewall 201 is disposed opposite to the side face 103 of the display module 10. The support post 204 and the plurality of heat dissipation protrusions 205 are disposed on a side of the first sidewall 201 facing the display module 10. The support post 204 contacts the side face of the display module 10 and has a height greater than the heat dissipation protrusions 205, such that a gap is formed between the display module 10 and the heat dissipation protrusions 205.

As a heat source, the display module 10 has a fixed power, i.e., a fixed heat source temperature (denoted as Tᵢₙ) in a normal working state or a full-load working state, while a surface temperature of an external structure of the product (denoted as Tₒᵤₜ) contacted by a user in use of the product is a design temperature value that is acceptable by a user. A thermal resistance in the heat dissipation process may be calculated by:
thermal resistance=(Tᵢₙ−Tₒᵤₜ)/P (unit: °C./W) (equation 1); and
thermal resistance=L/(K×S) (unit: K/W or °C./W) (equation 2),
where K is a thermal conductivity depending on characteristics of a material itself; 1 is a thickness of the material, which is in direct proportion to the thermal resistance, and a larger thickness means a higher thermal resistance and worse thermal conduction; and s is an area of the material, which is in inverse proportion to the thermal resistance, and a larger area means a lower thermal resistance and better thermal conduction.

In an embodiment of the present disclosure, the display module 10 is used as a whole heat source and contact the side frames 20, while at least one of the side frames 20 is provided with heat dissipation protrusions 205 at an inner side of the first sidewall 201. The provision of the heat dissipation protrusions 205 can effectively increase a heat exchange area between the side frame 20 and air inside the display apparatus, thereby increasing the heat exchange efficiency between the side frame 20 and air. In addition, since the first sidewall 201 may be further provided with a support post 204 having a height greater than the heat dissipation protrusions 205, an air interlayer may be formed between the heat dissipation protrusions 205 and the display module 10, which can increase the thermal resistance between the heat source and the side frame 20, and reduce the heat transfer efficiency between the heat source and the side frame 20, so that the temperature of an outer surface of the side frame 20 is reduced, and a user can be prevented from touching a high-temperature surface.

When a too small height difference D is provided between the support post 204 and the heat dissipation protrusions 205, it may be impossible to form an air interlayer due to machining dimensional tolerances of the product, thereby failing to achieve the thermal isolation effect by the air interlayer. In contrast, when a large small height difference D is provided between the support post 204 and the heat dissipation protrusions 205, a frame width of the display apparatus is increased, which will affect the appearance of the display product. In view of this, in an embodiment of the present disclosure, the height difference D between the support post 204 and the heat dissipation protrusions 205 is set to 0.05 to 0.15 times a height H1 of the heat dissipation protrusions 205, thereby achieving a good thermal isolation effect while avoiding a too wide frame of the display apparatus. For example, D is 0.05 times, or 0.07 times, or 0.09 times, or 0.11 times, or 0.15 times H1.

In one example, the height difference D between the support post 204 and the heat dissipation protrusions 205 is set in a range of 0.5 mm to 1 mm. For example, D is 0.5 mm, or 0.6 mm, or 0.7 mm, or 0.8 mm, or 1 mm.

In some embodiments, a thickness C of the first sidewall 201 is 0.15 to 0.45 times the height H1 of the heat dissipation protrusions 205, so as to ensure sufficient strength of the first sidewall 201.

In one example, the first sidewall 201 has a thickness C in a range of 1.5 mm to 3 mm, so as to ensure sufficient strength of the first sidewall 201. For example, C is 1.5 mm, or 2.0 mm, or 2.5 mm, or 3 mm.

In some embodiments, as shown in FIG. 6, at least one of the side frames 20 further includes a second sidewall 202 connected to the first sidewall 201. At least part of the second sidewall 202 is located on a side of the display module 10 away from the second face 102. A recess 202v is provided on a side of the second sidewall 202 facing the first face 101, so that an air interlayer is also formed between the second sidewall 202 and the display module 10, thereby further reducing the temperature of an outer surface of the side frame 20.

When the recess 202v has a too small depth E, it may be impossible to form an air interlayer due to machining dimensional tolerances of the product, thereby failing to achieve the thermal isolation effect by the air interlayer. When the recess 202v has a too large depth E, the thickness of the second sidewall 202 is increased, which may affect the appearance of the display apparatus. Therefore, in an embodiment of the present disclosure, the depth E of the recess 202v is set to 0.15 to 0.5 times the thickness of the second sidewall 202. For example, the depth E of the recess 202v is 0.15 times, or 0.25 times, 0.3 times, or 0.5 times the thickness of the second sidewall 202.

In some examples, the depth E of the recess 202v is set in a range of 0.5 mm to 1.0 mm, so that an air interlayer is ensured to be formed between the second sidewall 202 and the display module 10 without affecting the appearance of the display apparatus. For example, E is 0.5 mm, or 0.6 mm, or 0.7 mm, or 0.8 mm, or 0.9 mm, or 1.0 mm.

In some embodiments, the depth E of the recess 202v may be similar to or the same as the height difference D, so that the air interlayer formed between the first side 202 and the display module 10 has a thickness substantially equal to the air interlayer formed between the heat dissipation protrusions 205 and the display module 10, and the temperature distribution over the first sidewall 201 and the second sidewall 202 is more uniform.

In some embodiments, as shown in FIG. 6, the second sidewall 202 includes a first edge away from the first sidewall 201 and extending along a length direction of the side frame 20, and a distance F between the first edge and the recess 202v is 0.1 to 0.5 times the width of the second sidewall 202, so that a user will not see the internal structure of the display apparatus when viewing at a close large viewing angle (e.g., close to the side face of the display apparatus). For example, F is 0.1 times, or 0.3 times, or 0.5 times the width of the second sidewall 202.

In some embodiments, the distance F between the first edge and the recess 202v is in a range of 0.5 mm to 1.0 mm, so that a user will not see the internal structure of the display apparatus when viewing at a close large viewing angle. For example, F is 0.5 mm, or 0.6 mm, or 0.8 mm, or 1.0 mm.

In some embodiments, as shown in FIG. 6, a distance G between a recess bottom face of the recess 202v facing the first face 101 and a surface of the second sidewall 202 facing away from the first face 101 is greater than the depth of the recess 202v, so that the surface of the second sidewall 202 is ensured to have sufficient strength even after the recess 202v is formed.

It should be noted that the thickness of the second sidewall 202 refers to a maximum thickness of the second sidewall 202 at a position without the recess 202v. In other words, the thickness of the second sidewall 202 is equal to a sum of the above distance G and the depth of the recess 202v.

In some embodiments, G is in a range of 1.0 mm to 3.0 mm, so that the surface of the second sidewall 202 is ensured to have sufficient strength even after the recess 202v is formed, and the thickness of the second sidewall 202 will not become too large or affect the appearance of the product. For example, G is 1.0 mm, or 1.5 mm, or 2.0 mm, or 2.5 mm, or 3.0 mm.

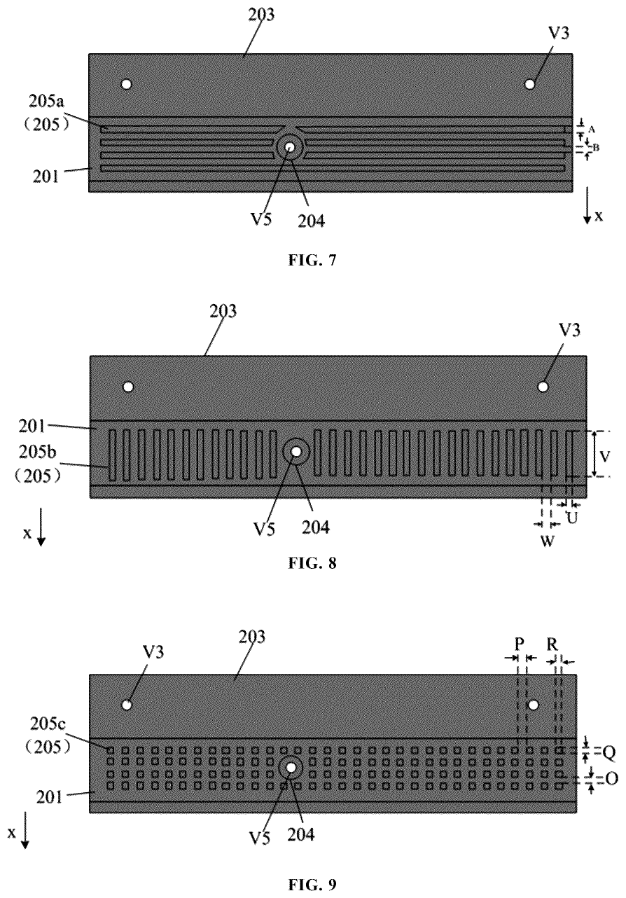

FIGS. 7 to 12 are six distribution patterns of heat dissipation protrusions according to some embodiments of the present disclosure. As shown in FIGS. 7 to 12, the plurality of heat dissipation protrusions 205 include: at least one of a plurality of first heat dissipation fins 205a, a plurality of second heat dissipation fins 205b, or a plurality of heat dissipation columns 205c. For example, as shown in FIG. 7, the plurality of heat dissipation protrusions 205 include a plurality of first heat dissipation fins 205a arranged along a thickness direction of the display module 10 (i.e., the x direction in FIGS. 4 and 7 to 11), and each first heat dissipation fin 205a extends along a length direction of the first sidewall 201.

For another example, as shown in FIG. 8, the plurality of heat dissipation protrusions 205 include a plurality of second heat dissipation fins 205b arranged in the length direction of the first sidewall 201, and each second heat dissipation fin 205b extends along the thickness direction of the display module 10.

For another example, as shown in FIG. 9, the plurality of heat dissipation protrusions 205 include a plurality of heat dissipation columns 205c arranged in an array. An orthographic projection of each heat dissipation column 205c on the first sidewall 201 may have a rectangular, circular, oval or triangular shape or the like, which is not specifically limited here.

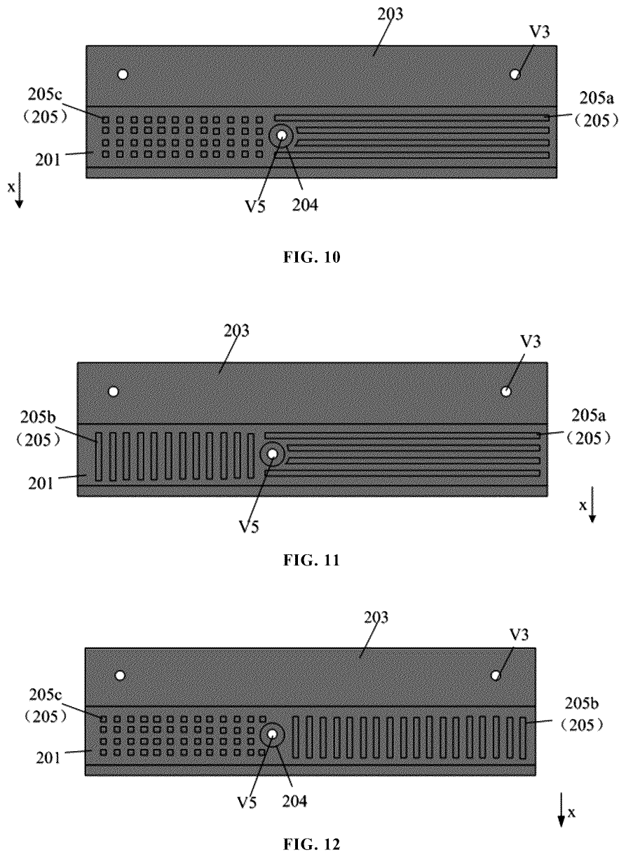

For another example, as shown in FIG. 11, the plurality of heat dissipation protrusions 205 include a plurality of the first heat dissipation fins 205a as described above, and a plurality of the second heat dissipation fins 205b as described above. For another example, as shown in FIG. 10, the plurality of heat dissipation protrusions 205 include a plurality of the first heat dissipation fins 205a as described above, and a plurality of heat dissipation columns 205c. For another example, as shown in FIG. 12, the plurality of heat dissipation protrusions 205 may include the second heat dissipation fins 205b as described above, and a plurality of heat dissipation columns 205c. For another example, the plurality of heat dissipation protrusions 205 may include a plurality of first heat dissipation fins 205a, a plurality of second heat dissipation fins 205b, and a plurality of heat dissipation columns 205c at the same time.

When the plurality of heat dissipation protrusions 205 include a plurality of first heat dissipation fins 205a, a thickness A of each first heat dissipation fin 205a may be 0.2 to 0.5 times a height of the heat dissipation fin, so that a contact area between the first heat dissipation fin 205a and air is increased while preventing the first heat dissipation fin 205a from being broken due to a too small thickness. For example, the thickness A of the first heat dissipation fin 205a is 0.2 to 0.3 times, or 0.3 to 0.4 times, or 0.4 to 0.5 times the height of the heat dissipation fin.

In some embodiments, the thickness A of the first heat dissipation fin 205a is in a range of 1.5 mm to 3 mm. For example, A is 1.0 mm, or 1.5 mm, or 2.0 mm, or 2.5 mm, or 3.0 mm.

In addition, a distance B between two adjacent first heat dissipation fins 205a is 0.5 to 1.25 times the thickness A of the first heat dissipation fin 205a, so that a sufficient air flow channel space is ensured to be formed between the adjacent first heat dissipation fins 205a, and heat in the first heat dissipation fins 205a can be sufficiently exchanged with air. For example, B is 0.5 to 0.8 times, or 0.8 to 1 times, or 1 to 1.25 times A.

In some embodiments, the distance B between two adjacent first heat dissipation fins 205a is greater than the height difference D between the support post 204 and the heat dissipation protrusions 205, so that an air flow channel between the first heat dissipation fins 205a can be fully communicated with the air interlayer between the support post 204 and the display module, and the influence of the heat source temperature on the temperature of the outer surface of the frame can be reduced.

In some embodiments, the distance B between two adjacent first heat dissipation fins 205ais in a range of 1.5 mm to 2.5 mm. For example, B is 1.5 mm, or 1.8 mm, or 2.0 mm, or 2.5 mm.

When the heat dissipation protrusions 205 include a plurality of second heat dissipation fins 205b, a thickness U of each second heat dissipation fin 205b is smaller than a height of the heat dissipation fin. For example, U is 0.2 to 0.5 times the height of the heat dissipation fin, so that a contact area between the second heat dissipation fin 205b and air is increased while preventing the second heat dissipation fin 205b from being broken due to a too small thickness. For example, the thickness U of the second heat dissipation fin 205b is 0.2 to 0.3 times, or 0.3 to 0.4 times, or 0.4 to 0.5 times the height of the heat dissipation fin.

In some embodiments, the thickness U of the second heat dissipation fin 205b is in a range of 1.5 mm to 3 mm. For example, U is 1.0 mm, or 1.5 mm, or 2.0 mm, or 2.5 mm, or 3.0 mm.

In addition, a length V of the second heat dissipation fin 205b may be between 20 mm and 24 mm, for example, 20 mm, 22 mm, or 24 mm.

In addition, the distance W between two adjacent second heat dissipation fins 205bis greater than the height difference D between the support post 204 and the heat dissipation protrusions 205, so that an air flow channel between the second heat dissipation fins 205b can be fully communicated with the air interlayer between the support post 204 and the display module, and the influence of the heat source temperature on the temperature of the outer surface of the frame can be reduced.

In some embodiments, the distance W between two adjacent second heat dissipation fins 205bis in a range of 1.5 mm to 2.5 mm. For example, W is 1.5 mm, or 1.8 mm, or 2.0 mm, or 2.5 mm.

When the heat dissipation protrusions 205 include a plurality of heat dissipation columns 205c, a size Q of each heat dissipation column 205c in the thickness direction of the display module 10 and a size R in the length direction of the first sidewall 201 are both 0.2 to 0.5 times the height of the heat dissipation column, so that a contact area between the heat dissipation column 205c and air is increased while preventing the heat dissipation column 205c from being broken due to a too small cross sectional area. For example, Q and R are 0.2 to 0.3 times, or 0.3 to 0.4 times, or 0.4 to 0.5 times the height of the heat dissipation column 205c.

In some embodiments, Q and R are both between 1.5 mm to 3 mm. For example, R and Q are both 1.0 mm, or 1.5 mm, or 2.0 mm, or 2.5 mm, or 3.0 mm.

In addition, a distance P between two adjacent heat dissipation columns 205c in the same row, and a distance O between two adjacent heat dissipation columns 205c in the same column, are both greater than the height difference D between the support post 204 and the heat dissipation protrusions 205, so that an air flow channel between the heat dissipation columns 205c can be fully communicated with the air interlayer between the support post 204 and the display module, and the influence of the heat source temperature on the temperature of the outer surface of the frame can be reduced.

In some embodiments, the distance P between two adjacent heat dissipation columns 205c in the same row may be equal to the distance O between two adjacent heat dissipation columns 205c in the same column, thereby improving the uniformity of the temperature distribution on the outer surface of the frame.

In some embodiments, the distance P between two adjacent heat dissipation columns 205c in the same row, and the distance O between two adjacent heat dissipation columns 205c in the same column, are both in a range of 1.5 mm to 2.5 mm, so that a sufficient air flow channel space is ensured to be formed between the plurality of heat dissipation columns 205c, and heat in the heat dissipation columns 205c can be sufficiently exchanged with air. For example, O is 1.5 mm, or 1.8 mm, or 2.0 mm, or 2.5 mm.

In some embodiments, as shown in FIGS. 7 to 12, a spacing region is formed between the support post 204 and the heat dissipation protrusions 205, thereby forming an air interlayer around the heat dissipation protrusions 205, and further reducing the heat transfer efficiency between the heat source and the side frame 20. In some embodiments, as shown in FIGS. 7, 9 and 14A, when the plurality of heat dissipation protrusions 205 adjacent to the support post 204 are the heat dissipation columns 205c or the first heat dissipation fins 205a, the spacing region between the support post 204 and the heat dissipation protrusions 205 may be an annular structure which may have a substantially circular ring shape.

The heat dissipation effects of the first heat dissipation fins 205a, the second heat dissipation fins 205b, and the heat dissipation columns 205c are compared below.

In the case of satisfying the above parameter settings, four first heat dissipation fins 205a may be provided within each 100 mm length range. Each first heat dissipation fin 205a has a height of 7.2 mm, a length of 100 mm, with two sides in contact with air. Then, a total area of the first heat dissipation fins 205a in contact with air within each 100 mm length range is: 7.2 mm*100 mm*4*2=5760 mm². Within each 100 mm length range, 136 heat dissipation columns 205c may be provided. A size R of each heat dissipation column 205c in the length direction of the first sidewall 201 is 1.5 mm, and a size Q of each heat dissipation column 205c in the thickness direction of the display module 10 is 2.5 mm. Then, a total contact area between the heat dissipation columns 205c and air within each 100 mm length range is: [7.2 mm*1.5 mm+7.2 mm*2.5]*136*2 =7833.6 mm². Within each 100 mm length range, 34 second heat dissipation fins 205b may be provided. Each second heat dissipation fin 205b has a height of 7.2 mm, and a size of the second heat dissipation fin 205b in the thickness direction of the display module 10 (i.e., the length of the second heat dissipation fin 205b) is 22 mm. Then, a total area of the second heat dissipation fins 205b in contact with air within each 100 mm length range is: 7.2 mm*22 mm*34*2=10771.2 mm². It can be seen that, compared with providing a plurality of first heat dissipation fins 205a, providing a plurality of heat dissipation columns 205c and/or a plurality of second heat dissipation fins 205b can further increase the heat dissipation area and improve the heat exchange efficiency between the side frame 20 and air.

In some embodiments, as shown in FIGS. 2 and 3, the plurality of side frames 20 include at least one first side frame 21 and at least one second side frame 22 located on two adjacent sides of the display module 10 and detachably connected. Each of the first side frame 21 and the second side frame 22 includes the first sidewall 201, the support post 204, and the heat dissipation protrusions 205.

In one example, as shown in FIGS. 2 and 3, the plurality of side frames 20 include one first side frame 21 and two second side frames 22. When the display apparatus is in an upright state, the first side frame 21 is the side frame 20 located on a top side of the display module 10, and the second side frames 22 are the side frames 20 located at left and right sides of the display module 10.

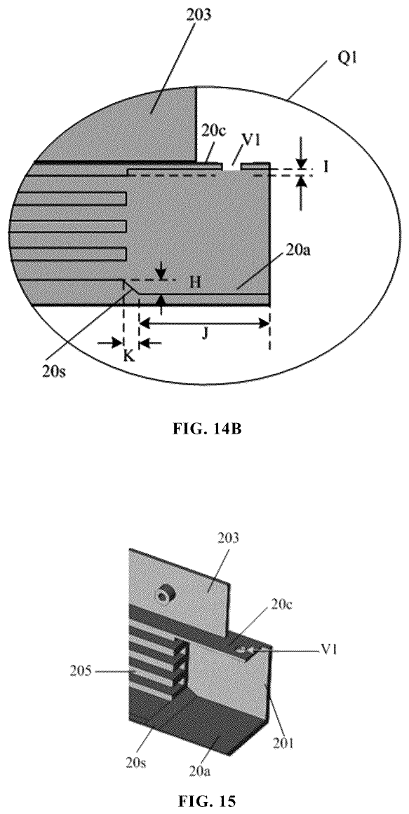

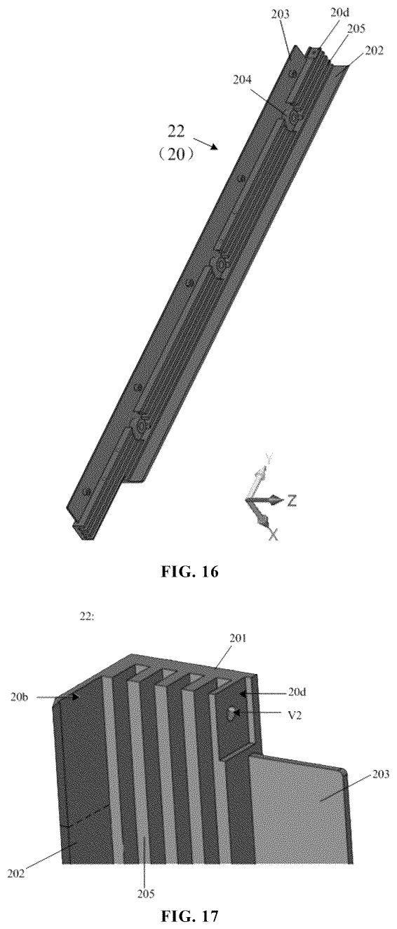

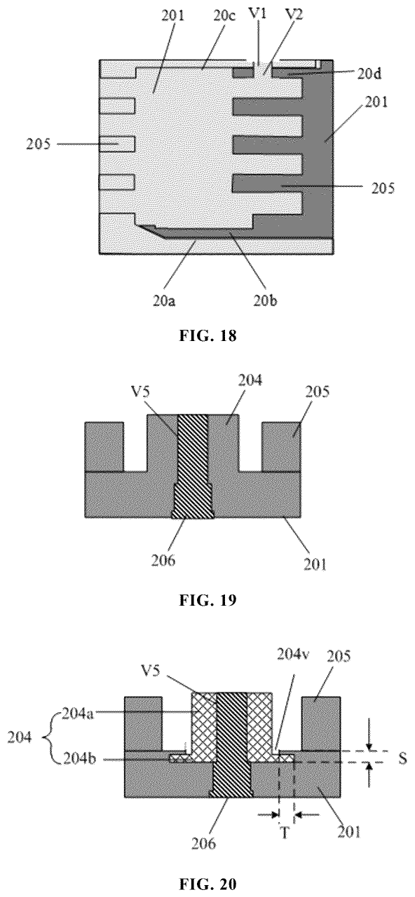

FIG. 14A is a plan view of a first side frame according to some embodiments of the present disclosure, FIG. 14B is an enlarged partial view of region Q1 in FIG. 14A, FIG. 15 is a perspective view of region Q1 in FIG. 14A, FIG. 16 is a perspective view of a second side frame according to some embodiments of the present disclosure, FIG. 17 is a partial perspective view of a second side frame according to some embodiments of the present disclosure, and FIG. 18 is a sectional view showing a connection position between a first side frame and a second side frame according to some embodiments of the present disclosure.

As shown in FIGS. 14A to 18, in some embodiments, each of the first side frame 21 and the second side frame 22 includes the first sidewall 201 and the second sidewall 202 as described above. A first mating part 20a is provided at an end of the second sidewall 202 of the first side frame 21 close to the second side frame 22, and the second sidewall 202 of the second side frame 22 includes a second mating part 20b matched with the first mating part 20a to form a first limit structure. The first side frame 21 further includes a third mating part 20c disposed opposite to the second sidewall 202 of the first side frame 21 and connected to the first sidewall 201 of the first side frame 21. The second side frame 22 further includes a fourth mating part 20d disposed opposite to the second sidewall 202 of the second side frame 22 and connected to the first sidewall 201 of the second side frame 22. The third mating part 20c is matched with the fourth mating part 20d to form a second limit structure.

The first limit structure and the second limit structure can limit positions of the first side frame 21 and the second side frame 22, and prevent relative movement therebetween.

In the embodiments of the present disclosure, specific structures of the first limit structure and the second limit structure are not limited as long as the first side frame 21 and the second side frame 22 can be limited. As a specific implementation of the present disclosure, the first limit structure and the second limit structure both adopt a mutual mortise-and-tenon structure to reduce a splicing seam between the first side frame 21 and the second side frame 22.

Specifically, the first mating part 20a includes a first mortise on the second sidewall 202 of the first side frame 21. Specifically, the second mating part 20b may be a part of the second sidewall 202 of the second side frame 22 close to the first side frame 21, and the second mating part 20b is inserted into the first mortise in the first side frame 21. In some embodiments, the first mortise includes a first bottom face facing the third mating part 20c, and a first side face 20s connected to the first bottom face. The second mating part 20b includes a second side face 20s attached to the first side face. The first side face 20s and the second side face are both inclined. The abutment between the incline faces of the second mating part 20b and the first mortise can help to buffer collisions between the second mating part 20b and the first side frame 21.

A too small depth H of the first mortise cannot enable effective limiting; while a too large depth of the first mortise may affect the strength of the second sidewall 202 of the first side frame 21. In view of this, in some embodiments, as shown in FIG. 14B, the depth H of the first mortise is set to in a range of 1.5 mm to 2.5 mm, so that the second side frame 22 can be effectively limited while ensuring the strength of the second sidewall 202 of the first side frame 21. For example, the depth H of the first mortise is 1.5 mm, or 1.8 mm, or 2.0 mm, or 2.2 mm, or 2.5 mm.

In some embodiments, a size J of the first mortise in the length direction of the first side frame 21 may be equal to the width of the sidewall of the second side frame 22. For example, J is between 20 mm and 30 mm.

In some embodiments, a size K of the first side face 20s in the length direction of the first side frame 21 is between 1 mm and 2 mm, and an angle between the first side face 20s and the first bottom face is between 120° and 150°. For example, the angle between the first side face and the first bottom face is 120°, or 130°, or 145°, or 150°.

In some embodiments, the third mating part 20c and the fourth mating part 20d may form a mutual mortise-and-tenon structure. For example, a second mortise is provided on a side of the third mating part 20c facing the second sidewall 202 of the first side frame 21, a third mortise is provided on a side of the fourth mating part 20d facing away from the second sidewall 202 of the second side frame 22, the third mating part 20c is inserted into the third mortise, and the fourth mating part 20d is inserted into the second mortise.

The second mortise may have a depth I in a range of 1.5 mm to 2.5 mm, so that the second side frame 22 can be effectively limited while ensuring the strength of the first side frame 21. For example, the depth I of the second mortise is 1.5 mm, or 1.8 mm, or 2.0 mm, or 2.2 mm, or 2.5 mm.

A size J′ of the second mortise in the length direction of the first side frame 21 may be equal to J, and the third mortise may have the same depth as the second mortise.

In some embodiments, a first mounting hole V1 is provided in the third mating part 20c, and a second mounting hole V1 opposite to the first mounting hole V2 is provided in the fourth mating part 20d. The display apparatus further includes a first fastener running through the first mounting hole V1 and the second mounting hole V2 and configured to detachably connect the first side frame 21 and the second side frame 22. For example, the first fastener may be a bolt, while each of the first mounting hole V1 and the second mounting hole V2 may be a threaded hole.

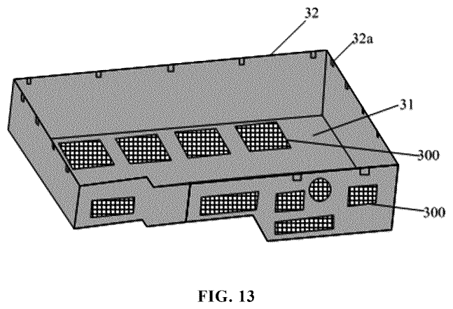

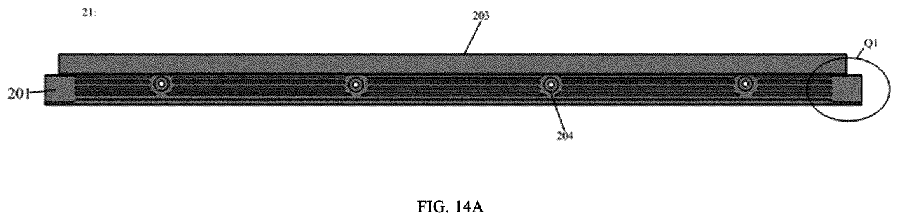

In some embodiments, as shown in FIGS. 1 and 4, the display apparatus further includes a rear case 30. FIG. 13 is a schematic diagram of a rear case according to some embodiments of the present disclosure. As shown in FIGS. 4 and 13, the rear case 30 includes a case bottom wall 31 and a case sidewall 32 connected to the case bottom wall 31. The case bottom wall 31 and the case sidewall 32 define a receiving space, and the case bottom wall 31 is located on a side of the receiving space away from the display module 10.

As shown in FIG. 4, at least one of the side frames 20 further includes a mounting wall 203 fixedly connected to the first sidewall 201 and located in the receiving space. The mounting wall 203 is connected to the case sidewall 32.

In some embodiments, the mounting wall 203 and the first sidewall 201 may be connected into an integral structure.

In some embodiments, as shown in FIGS. 4 and 7, the mounting wall 203 is provided with a third mounting hole V3, and the case sidewall 32 is provided with a fourth mounting hole. The display apparatus further includes a second fastener 41 running through the fourth mounting hole and extending into the third mounting hole V3, and configured to detachably connect the mounting wall 203 and the case sidewall 32. For example, the second fastener 41 is a screw, while each of the third mounting hole V3 and the fourth mounting hole is a threaded hole. The case sidewall 32 includes a concave part 32a in which the fourth mounting hole is provided.

By forming the concave part 32a in the case sidewall 32, point contact can be made between the case sidewall 32 and the mounting wall 203, thereby reducing the temperature of an outer surface of the case sidewall 32, and the provision of the concave part 32a can provide a hidden space for a screw cap, thereby improving the appearance of the display apparatus.

The concave part 32a may be formed by stamping, with a stamping depth between 1.0 mm and 2.5 mm, and a stamping width determined according to a diameter of the screw cap. For example, if the screw cap has a diameter between 7 mm to 20 mm, the stamping width may be between 15 mm to 30 mm, so that the screw cap can be hidden.

In some embodiments, as shown in FIG. 13, each of the case bottom wall 31 and the case sidewall 32 may be provided with heat dissipation holes 300 for dissipating heat generated by the display apparatus.

FIG. 19 is a schematic diagram of a support post and a first sidewall according to some embodiments of the present disclosure, and FIG. 20 is an another schematic diagram of a support post and a first sidewall according to some embodiments of the present disclosure. As shown in FIG. 19, in some embodiments, the support post 204 and the first sidewall 201 may be connected into an integral structure.

The support post 204 and the first sidewall 201 are both conductors, so that static charges on the display module 10 can be quickly transferred to the side frame 20 in a static test process of the display apparatus, and then released to prevent display defects caused by static electricity introduced into circuit devices inside the display module 10.

In other embodiments, as shown in FIG. 20, a part of the support post 204 is embedded into the first sidewall 201. Specifically, the support post 204 is a conductor, including a support body 204a and an embedded part 204b connected to the support body 204a. The support body 204a is located on a side of the embedded part 204b facing the display module 10, and an orthographic projection of the embedded part 204b on the side face of the display module 10 covers and exceeds an orthographic projection of the support body 204a on the side face of the display module 10. The embedded part 204b is embedded into the first sidewall 201.

The support post 204 and the first sidewall 201 are both conductors, so that static charges on the display module 10 can be quickly transferred to the side frame 20 in a static test process of the display apparatus. Further, since a part of the support post 204 is embedded into the first sidewall 201, the support post 204 can transfer the static electricity from the display module 10 to the side frame 20 even if the side frame 20 is coated with an insulation layer such as an anti-oxidation layer.

The embedded part 204b is embedded into the first sidewall 201 by a depth S in a range of 1.5 mm to 2.5 mm, so that a tensile strength of the support post 204 can be improved, and the support post 204 can be prevented from falling off in use of the display apparatus; at the same time, the outer surface of the side frame 20 is prevented from being marked. For example, S is 1.5 mm, or 1.7 mm, or 2.0 mm, or 2.2 mm, or 2.5 mm.

In some embodiments, the first sidewall 201 is provided with an embedded groove 204v, and the embedded part 204b is embedded into the first sidewall 201 from a sidewall of the embedded groove 204v. The embedded part 204b has a larger cross-sectional area than the embedded groove 204v. The cross-sectional area herein means an area of a cross section in a direction perpendicular to the thickness direction of the first sidewall 201.

The embedded part 204b is embedded into the first sidewall 201 by a width T in a range of 1.0 mm to 2.0 mm, so that a tensile strength of the support post 204 is improved, and the support post 204 is prevented from falling off in use of the display apparatus, while reducing the embedding difficulty of the embedded part 204b and avoiding waste of material. For example, T is 1.0 mm, or 1.3 mm, or 1.5 mm, or 1.8 mm, or 2.0 mm.

In some embodiments, as shown in FIGS. 7, 19 and 20, the support post 204 is provided with a fifth mounting hole V5, and the display apparatus further includes a fifth fastener 206 running through the fifth mounting hole V5 and connected to the display module 10.

For example, the fifth fastener 206 is a screw, the display module 10 is provided with a threaded hole corresponding to the fifth mounting hole V5, and the fifth fastener 206 passes through the fifth mounting hole V5 to be screwed into the threaded hole in the display module 10.

As shown in FIG. 5, the display module 10 may include: a display panel 11, a backlight, a middle frame 16, and a front frame 13. The display panel 11 is stacked on a light-emitting side of the backlight. The backlight may include a back plate 12 and an optical film set 15. The back plate 12 includes a back plate sidewall 122 and a back plate bottom wall 121 connected with each other to define a receiving space. At least part of the optical film set 15 is located in the receiving space. The middle frame 16 includes a retaining wall part 161, and a bearing part 162 connected to the retaining wall part 161. An edge of the display panel 11 is disposed on the bearing part 162. The front frame 13 includes a front frame sidewall 131, and a shielding part 132 connected to the front frame sidewall 131. The shielding part 132 covers the retaining wall part 161 and a non-display region of the display panel 11. The fifth fastener 206 may be coupled to the front frame 13 of the display module 10.

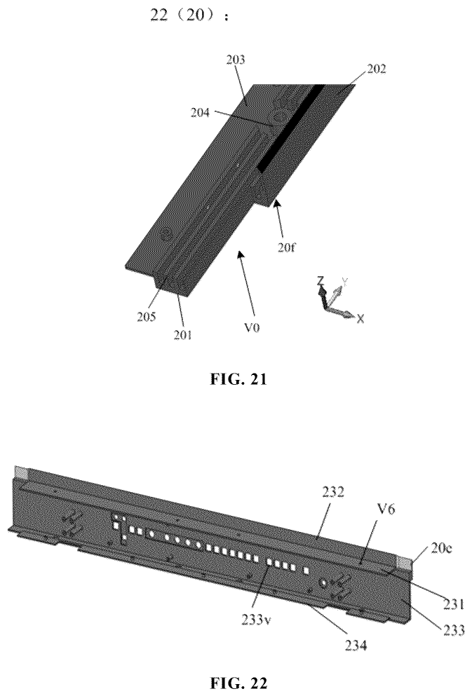

In some embodiments, as shown in FIGS. 2 and 3, the plurality of side frames 20 at the periphery of the display module 10 further include a third side frame 23. The third side frame 23 and the first side frame 21 are located at two opposite sides of the display module 10, and two ends of the third side frame 23 are detachably connected to the two second side frames 22, respectively. FIG. 21 is a perspective view of a second side frame at a position close to a third side frame according to some embodiments of the present disclosure, and FIG. 22 is a schematic diagram of a third side frame according to some embodiments of the present disclosure. As shown in FIG. 22, the third side frame 23 may have a different structure from the first side frame 21 and the second side frame 22. The third side frame 23 includes: a third sidewall 231, a fourth sidewall 232, a fifth sidewall 233, and a sixth sidewall 234. The third sidewall 231 is disposed opposite to the side face of the display module 10, and connected to the display module 10 by a fastener. For example, the third sidewall 231 is provided with a sixth mounting hole, and the fastener passes through the sixth mounting hole to be connected to the display module 10. When the display apparatus is in an upright state, the third sidewall 231 can support the display module 10.

The fourth sidewall 232 is connected to the third sidewall 231, at least part of the fourth sidewall 232 is disposed opposite to the first face 101 of the display module 10, and the fourth sidewall 232 may include a fifth mating part 20e. As shown in FIG. 21, the second sidewall 202 of the second side frame 22 includes a sixth mating part 20f matched with the fifth mating part 20e to form a third limit structure. The fifth mating part 20e may be a third mortise formed in the fourth sidewall 232, the sixth mating part 20f may be a part of the second sidewall 202 of the second side frame 22 close to the fourth sidewall 232, and the sixth mating part 20f is inserted into the third mortise. The fourth sidewall 232 and the sixth mating part 20f may be further provided with mounting holes, so that the fastener passes through the mounting holes in the fourth sidewall 232 and the sixth mating part 20f to connect the second side frame 22 and the third side frame 23.

The fifth sidewall 233 is connected to the third sidewall 231, and an orthographic projection of the fifth sidewall 233 on the case bottom wall 31 of the rear case 30 may be not overlapped with an orthographic projection of the display module 10 on the case bottom wall 31. A key board may be provided on a side of the fifth sidewall 233 close to the rear case bottom wall 31, and a window 233v may be defined in the fifth sidewall 233, so that keys on the key board and indicator lights can be exposed.

The sixth sidewall 234 is connected to the third sidewall 231, and connected to the case sidewall 32 of the rear case 30. For example, the sixth sidewall 234 may be provided with a seventh mounting hole, and the case sidewall 32 may be provided with an eighth mounting hole, so that the fastener passes through the seventh mounting hole and the eighth mounting hole to connect the case sidewall 32 and the sixth sidewall 234. A concave part 32a may also be formed in the case sidewall 32 at a position corresponding to the eighth mounting hole, so that the fastener can be hidden.

As shown in FIG. 21, the second sidewall 202 of the second side frame 22has a length smaller than the first sidewall 201, so that the second side frame 22 forms an avoiding notch VO near the third side frame 23 to avoid the fifth sidewall 233.

It will be appreciated that the above implementations are merely exemplary implementations for the purpose of illustrating the principle of the present disclosure, and the present disclosure is not limited thereto. Various modifications and improvements can be made by a person having ordinary skill in the art without departing from the spirit and essence of the disclosure. Accordingly, all of the modifications and improvements also fall into the protection scope of the present disclosure.

1. A display apparatus, comprising:
a display module comprising a first face and a second face opposite to each other, and a side face connected between the first face and the second face, wherein at least part of the first face is a display surface; and
a plurality of side frames at a periphery of the display module, wherein at least one of the side frames comprises a first sidewall, and a support post and a plurality of heat dissipation protrusions arranged at intervals on the first sidewall, the first sidewall is opposite to the side face of the display module, the support post and the plurality of heat dissipation protrusions are on a side of the first sidewall facing the display module, and the support post contacts the side face of the display module and has a height greater than the heat dissipation protrusions, such that a gap is formed between the display module and the heat dissipation protrusions.

2. The display apparatus according to claim 1, wherein a height difference between the support post and the heat dissipation protrusions is in a range of 0.5 mm to 1 mm.

3. The display apparatus according to claim 1, wherein the first sidewall has a thickness in a range of 1.5 mm to 3 mm.

4. The display apparatus according to claim 1, wherein at least one of the side frames further comprises a second sidewall connected to the first sidewall, wherein at least part of the second sidewall is on a side of the display module away from the second face; and
a recess is provided on a side of the second sidewall facing the first face.

5. The display apparatus according to claim 4, wherein the recess has a depth in a range of 0.5 mm to 1.0 mm.

6. The display apparatus according to claim 4, wherein the second sidewall comprises a first edge away from the first sidewall and extending along a length direction of the side frame, and a distance between the first edge and the recess is in a range of 0.5 mm to 1.0 mm.

7. The display apparatus according to claim 4, wherein a distance between a recess bottom face of the recess facing the first face and a surface of the second sidewall facing away from the first face is in a range of 1.0 mm to 3.0 mm.

8. The display apparatus according to claim 1, wherein the plurality of heat dissipation protrusions comprise: at least one of a plurality of first heat dissipation fins, a plurality of second heat dissipation fins, or a plurality of heat dissipation columns;
wherein the plurality of first heat dissipation fins are arranged in a thickness direction of the display module, and each first heat dissipation fin extends along a length direction of the first sidewall;
the plurality of second heat dissipation fins are arranged in the length direction of the first sidewall, and each second heat dissipation fin extends along the thickness direction of the display module; and
the plurality of heat dissipation columns are arranged in an array.

9. The display apparatus according to claim 8, wherein the heat dissipation protrusions comprise the plurality of first heat dissipation fins, each of which has a thickness in a range of 1.5 mm to 3 mm, and a distance between two adjacent first heat dissipation fins is in a range of 1.5 mm to 2.5 mm.

10. The display apparatus according to claim 8, wherein the plurality of heat dissipation protrusions comprise the plurality of second heat dissipation fins, each of which has a thickness in a range of 1.5 mm to 3 mm, and a distance between two adjacent second heat dissipation fins is in a range of 1.5 mm to 2.5 mm.

11. The display apparatus according to claim 8, wherein the plurality of heat dissipation protrusions comprise the plurality of heat dissipation columns, each of which has a size in the thickness direction of the display module and a size in the length direction of the first sidewall both in a range of 1.5 mm to 3 mm, and a distance between two adjacent heat dissipation columns in a same row and a distance between two adjacent heat dissipation columns in a same column are both in a range of 1.5 mm to 2.5 mm.

12. The display apparatus according to claim 1, wherein the plurality of side frames comprise at least one first side frame and at least one second side frame on two adjacent sides of the display module and detachably connected; and
each of the first side frame and the second side frame comprises the first sidewall, the support post, and the heat dissipation protrusions.

13. The display apparatus according to claim 12, wherein each of the first side frame and the second side frame comprises a second sidewall connected to the first sidewall and at least partially on a side of the display module away from the second face;
a first mating part is provided at an end of the second sidewall of the first side frame close to the second side frame, and the second sidewall of the second side frame comprises a second mating part matched with the first mating part to form a first limit structure; and
the first side frame further comprises a third mating part opposite to the second sidewall of the first side frame and connected to the first sidewall of the first side frame; the second side frame further comprises a fourth mating part opposite to the second sidewall of the second side frame and connected to the first sidewall of the second side frame; and the third mating part is matched with the fourth mating part to form a second limit structure.

14. The display apparatus according to claim 13, wherein the first mating part comprises a mortise structure on the first side frame and comprising a first bottom face facing the third mating part and a first side face connected to the first bottom face; and the second mating part comprises a second side face attached to the first side face, wherein the first side face and the second side face are both inclined.

15. The display apparatus according to claim 13, wherein a first mounting hole is provided in the third mating part, and a second mounting hole opposite to the first mounting hole is provided in the fourth mating part; and the display apparatus further comprises a first fastener running through the first mounting hole and the second mounting hole and configured to detachably connect the first side frame and the second side frame.

16. The display apparatus according to claim 1, wherein the display apparatus further comprises a rear case comprising a case bottom wall and a case sidewall connected to the case bottom wall, the case bottom wall and the case sidewall define a receiving space, and the case bottom wall is on a side of the receiving space away from the display module; and
the side frame further comprises a mounting wall fixedly connected to the first sidewall and located in the receiving space, and the mounting wall is connected to the case sidewall.

17. The display apparatus according to claim 16, wherein the mounting wall is provided with a third mounting hole, and the case sidewall is provided with a fourth mounting hole; the display apparatus further comprises a second fastener running through the fourth mounting hole and extending into the third mounting hole, and configured to detachably connect the mounting wall and the case sidewall; and
the case sidewall comprises a concave part in which the fourth mounting hole is provided.

18. The display apparatus according to claim 1, wherein the support post is connected to the first sidewall to form an integral structure.

19. The display apparatus according to claim 1, wherein the support post is a conductor, comprising a support body and an embedded part connected to the support body, the support body is on a side of the embedded part facing the display module, and an orthographic projection of the embedded part on the side face of the display module covers and exceeds an orthographic projection of the support body on the side face of the display module; and the embedded part is embedded into the first sidewall,
wherein the embedded part is embedded into the first sidewall by a depth in a range of 1.5 mm to 2.5 mm, and/or
the first sidewall is provided with an embedded groove, the embedded part is embedded into the first sidewall from a sidewall of the embedded groove, and the embedded part is embedded into the first sidewall by a width in a range of 1.0 mm to 2.0 mm.

20-21. (canceled)

22. The display apparatus according to claim 1, wherein the support post is provided with a fifth mounting hole, and the display apparatus further comprises a fifth fastener running through the fifth mounting hole and connected to the display module.
